(19) United States
(12) Patent Application Publication
(10) Pub. No.: US 2026/0176432 A1
(43) Pub. Date: Jun. 25, 2026

(54) PREPREG, LAMINATED PLATE, PRINTED WIRING BOARD, AND SEMICONDUCTOR PACKAGE

(71) Applicant: Resonac Corporation, Minato-ku, Tokyo (JP)

(72) Inventors: Fumitaka UENO, Minato-ku, Tokyo (JP); Yukio NAKAMURA, Minato-ku, Tokyo (JP); Shiori MATSUOKA, Minato-ku, Tokyo (JP); Kohta IWANAGA, Minato-ku, Tokyo (JP); Shota NAKAMURA, Minato-ku, Tokyo (JP)

(21) Appl. No.: 19/129,108

(22) PCT Filed: Nov. 24, 2023
(86) PCT No.: PCT/JP2023/042266

§ 371 Date: May 12, 2025

(30) Foreign Application Priority Data
Nov. 25, 2022 (JP) 2022-188013

(51) Int. Cl. C08J 5/24; B32B 5/02; B32B 15/08; B32B 15/20; B32B 27/12; B32B 27/20; B32B 27/28; C08L 79/08; H10W 70/695

(52) U.S. Cl. CPC C08J 5/244; B32B 5/024; B32B 15/08; B32B 15/20; B32B 27/12; B32B 27/20; B32B 27/281; C08L 79/085; H10W 70/695; B32B 2250/40; B32B 2262/101; B32B 2264/1021; B32B 2264/202; B32B 2264/302; B32B 2270/00; B32B 2307/204; B32B 2307/538; B32B 2457/08; C08J 2379/08; C08J 2447/00; C08J 2453/02; C08J 2471/12; C08J 2479/08; C08L 2205/025; C08L 2205/03; C08L 2205/035; C08L 2205/08

(57) ABSTRACT

Provided is a prepreg or the like which has reduced adhesiveness between prepregs despite the fact that the prepreg contains a compound having a structural unit derived from a conjugated diene compound. Specifically, the prepreg is a prepreg having a concave-convex shape on the surface, the prepreg containing a thermosetting resin composition having (A) a thermosetting resin and (B) a compound having a structural unit (b1) derived from a conjugated diene compound, or a semi-cured product of the thermosetting resin composition, in which an existing ratio of a concave portion in the concave-convex shape is 30 to 90%.

### TECHNICAL FIELD

The present disclosure relates to a prepreg, a laminate, a printed wiring board, and a semiconductor package.

### BACKGROUND ART

In various electronic devices such as a mobile communication device represented by a mobile phone, a base station device thereof, a network infrastructure device such as a server and a router, and a large-sized computer, an increase in speed and capacity of a signal to be used has been progressing year by year. Accordingly, printed wiring boards mounted on these electronic devices are required to support higher frequencies, and a substrate material having excellent dielectric characteristics (relative dielectric constant and dielectric dissipation factor) in a high frequency band (for example, a high frequency band equal to or higher than the 10 GHz band) capable of reducing transmission loss is required. In recent years, in addition to the above-described electronic devices, in the ITS field related to automobiles, transportation systems, and the like, and in the indoor short-distance communication field, practical use or practical use plans of new systems handling high frequency radio signals have been advanced, and substrate materials with low transmission loss are required for printed wiring boards mounted on these devices.

As one of materials used for a printed wiring board required to have a low transmission loss, an elastomer known to have excellent dielectric characteristics is exemplified. For example, it is known that the dielectric characteristics are improved by incorporating a styrene-based thermoplastic elastomer into a resin composition containing (A) one or more selected from the group consisting of a maleimide compound having two or more N-substituted maleimide groups and derivatives thereof, (B) a polyphenylene ether resin, and (C) an organometallic compound having an alkoxy group bonded to a metal atom (see, for example, PTL 1).

### CITATION LIST

### Patent Literature

PTL 1: JP 2021-138849 A

### SUMMARY OF INVENTION

### Technical Problem

However, as a result of further studies by the present inventors, it has been found that when a plurality of prepregs formed using a resin composition containing a compound having a structural unit derived from a conjugated diene compound such as a styrene-based thermoplastic elastomer are stacked, they tend to adhere to each other and become difficult to peel off. Therefore, it was found that at the time of conveying the prepreg and at the time of producing the laminate, it is sometimes difficult to perform an operation of once peeling and then re-stacking the prepregs firmly adhered to each other in order to align the vertical and horizontal directions of the prepregs, which may cause a problem in industrial implementation.

In view of such circumstances, an object of the present disclosure is to provide a prepreg in which adhesiveness between prepregs is reduced even though the prepreg contains a compound having a structural unit derived from a conjugated diene compound, and to provide a laminate, a printed wiring board, and a semiconductor package that are obtained by using the prepreg.

### Solution to Problem

As a result of intensive studies, the present inventors have found that the above object can be achieved with the prepreg of the present disclosure.

The present disclosure includes the following embodiments [1] to [12].
[1]A prepreg having a concave-convex shape on the surface, the prepreg containing a thermosetting resin composition containing (A) a thermosetting resin and (B) a compound having a structural unit (b1) derived from a conjugated diene compound, or a semi-cured product of the thermosetting resin composition, in which an existing ratio of a concave portion in the concave-convex shape is 30 to 90%.
[2] The prepreg according to the item [1], in which the prepreg has a surface roughness (Rz) of 12.0 μm or more.
[3] The prepreg according to the item [1] or [2], in which the component (A) contains at least one selected from the group consisting of an epoxy resin, a maleimide compound, a phenol resin, a polyimide resin, a cyanate resin, an isocyanate resin, a benzoxazine resin, an oxetane resin, an amino resin, an unsaturated polyester resin, an allyl resin, a dicyclopentadiene resin, a silicone resin, a triazine resin, and a melamine resin.
[4] The prepreg according to any one of the items [1] to [3], in which in the component (B), the structural unit (b1) derived from a conjugated diene compound is a 1,2-bond unit of butadiene, a 1,4-bond unit of butadiene, a 3,4-bond unit of isoprene, a 1,4-bond unit of isoprene, or a bond unit in which at least one selected from these bond units is hydrogenated.
[5] The prepreg according to any one of the items [1] to [4], in which in the thermosetting resin composition, a content of the component (B) is 1% by mass or more and less than 14% by mass with respect to a total sum of resin components.
[6] The prepreg according to any one of the items [1] to [5], in which the thermosetting resin composition further contains (C) an inorganic filler.
[7] The prepreg according to the item [6], in which in the thermosetting resin composition, a content of the component (C) is 1 to 50% by volume with respect to a total sum of solid contents.
[8] The prepreg according to any one of the items [1] to [7], in which the thermosetting resin composition further contains (D) a compatibilizer.
[9] The prepreg according to any one of the items [1] to [8], in which the thermosetting resin composition further contains (E) a curing accelerator.
[10]A laminate including a cured product of the prepreg according to any one of the items [1] to [9], and a metal foil.
[11]A printed wiring board including a cured product of the prepreg according to any one of the items [1] to [9].
[12]A semiconductor package including the printed wiring board according to the item [11], and a semiconductor element.

### Advantageous Effects of Invention

According to the present disclosure, it is possible to provide a prepreg in which adhesiveness between prepregs is reduced even though the prepreg contains a compound having a structural unit derived from a conjugated diene compound, and to provide a laminate, a printed wiring board, and a semiconductor package that are obtained by using the prepreg.

### BRIEF DESCRIPTION OF DRAWINGS

FIG. 1 is a program set by Python at the time of binarization processing.

FIG. 2 is an SEM image (left figure) and an image resulting from binarization processing of the SEM image (right figure) of a prepreg surface in Example 1.

FIG. 3 is an SEM image (left figure) and an image resulting from binarization processing of the SEM image (right figure) of a prepreg surface in Example 2.

FIG. 4 is an SEM image (left figure) and an image resulting from binarization processing of the SEM image (right figure) of a prepreg surface in Comparative Example 1.

FIG. 5 is an SEM image (left figure) and an image resulting from binarization processing of the SEM image (right figure) of a prepreg surface in Comparative Example 2.

FIG. 6 is an SEM image (left figure) and an image resulting from binarization processing of the SEM image (right figure) of a prepreg surface in Comparative Example 3.

FIG. 7 is an SEM image (left figure) and an image resulting from binarization processing of the SEM image (right figure) of a prepreg surface in Comparative Example 4.

### DESCRIPTION OF EMBODIMENTS

In the numerical range described in the present disclosure, the upper limit value or the lower limit value of the numerical range may be replaced by the value described in the examples. In addition, the lower limit value and the upper limit value of the numerical range are arbitrarily combined with the lower limit value or the upper limit value of another numerical range, respectively. In the notation of the numerical range “AA to BB”, the numerical values AA and BB at both ends are included in the numerical range as the lower limit value and the upper limit value, respectively.

In the present disclosure, for example, the description of “10 or more” means 10 and a numerical value exceeding 10, and the same applies to a case where the numerical value is different. Further, for example, the description of “10 or less” means 10 and a numerical value less than 10, and the same applies to a case where the numerical value is different.

The components and materials exemplified in the present disclosure may be used alone or in combination of two or more kinds thereof, unless otherwise specified. In the present disclosure, when a plurality of substances corresponding to each component are present in a composition, the content of each component in the composition means the total amount of the plurality of substances present in the composition, unless otherwise specified.

In the present disclosure, the “resin component” refers to all components excluding inorganic compounds such as an inorganic filler which will be described later among the solid contents constituting the resin composition.

In the present disclosure, the “solid content” means a component other than a solvent, and a component that is liquid at 25° C. is also regarded as a solid content.

In the expression “containing (including) XX” described in the present disclosure, when XX can react, XX may be contained in a reacted state, XX may be simply contained as it is, or both of these aspects may be included.

An aspect in which matters described in the present disclosure are arbitrarily combined is also included in the present disclosure and the present embodiment.

### [Prepreg]

The prepreg of the present embodiment is as follows.

A prepreg having a concave-convex shape on the surface, the prepreg containing a thermosetting resin composition containing (A) a thermosetting resin and (B) a compound having a structural unit (b1) derived from a conjugated diene compound, or a semi-cured product of the thermosetting resin composition, in which an existing ratio of a concave portion in the concave-convex shape is 30 to 90%.

However, the “surface” does not include a surface in the thickness direction of the prepreg, that is, a side surface of the prepreg.

In the concave-convex shape on the surface of the prepreg of the present embodiment, since the existing ratio of the concave portion is 30 to 90%, the adhesiveness between the prepregs is reduced even though the component (B) causing the adhesiveness between the prepregs is contained. The reason why the effect is obtained is presumed as follows. It is considered that by setting the existing ratio of the concave portion to be 30 to 90% in the concave-convex shape, the contact area is reduced when the prepregs are stacked with each other, and as a result, the adhesiveness can be reduced to such an extent that there is no problem in industrial implementation. Whether or not the presumption is correct does not affect the scope of the present disclosure.

In the concave-convex shape on one surface or both surfaces of the prepreg, the existing ratio of the concave portion is preferably 30 to 90%, and based on the above presumption, the existing ratio of the concave portion is more preferably 30 to 90% on each of both surfaces of the prepreg.

The existing ratio of the concave portion in the concave-convex shape of the prepreg surface of the present embodiment is obtained by performing binarization processing of an image obtained by observing an arbitrary range of 524.2 μm×669.2 μm of the prepreg surface with a SEM (scanning electron microscope) to acquire a binarized image, and obtaining the existing ratio from an existing ratio of white and black in the binarized image, and the existing ratio of black was defined as the existing ratio of the concave portion. The observation by the SEM may be performed at a single location. However, in a case where the observation is performed at a plurality of locations, it is sufficient that the existing ratio of the concave portion is within the above range at one of the locations. However, it is preferable that the existing ratio of the concave portion is within the above range at half or more of the locations, it is more preferable that the existing ratio of the concave portion is within the above range at 80% or more of the locations, and it is still more preferable that the existing ratio of the concave portion is within the above range at all of the locations. The SEM image can have a magnification of 50 to 500 times, or can have a magnification of 100 times.

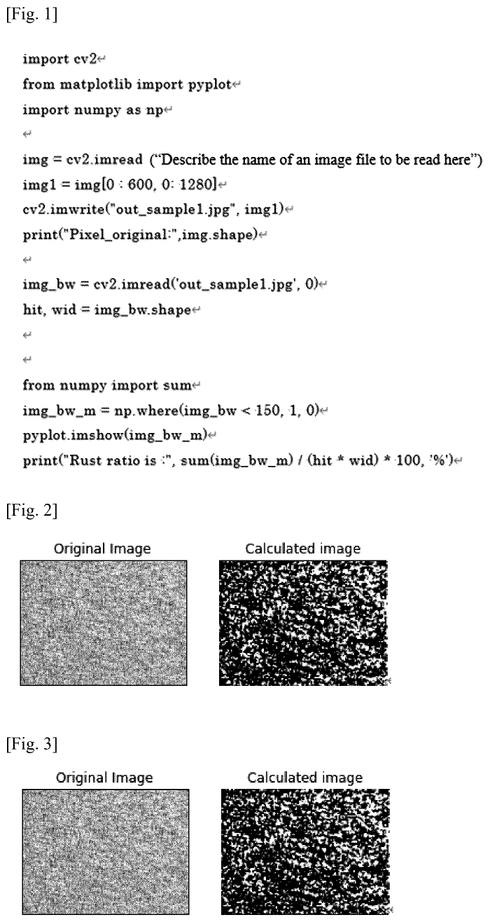

In the binarization processing, although not particularly limited, a binarized image can be obtained by setting the program shown in FIG. 1 using the programming language “Python 3.7.9”.

The program shown in FIG. 1 set by Python will be briefly described below.
import cv2: This is a program for reading an Open CV2 library.
from matplotlib import pyplot: This is a program for reading pyplot in matplotlib for graph drawing.
import numpy as np: This is a program for reading a library of numpy and defining numpy as np.
img=cv2.imread: This is a program for reading an image. The name of an image file to be read is input to the portion of “Describe the name of an image file to be read here” described above.
img1=img[0:600, 0:1280]: This is a program for designating the size of an image to be read.
cv2.imwrite(“out_sample1.jpg”, img1): This is a program for saving an image designated based on numpy information in CV2 as sample1.jpg.
print(“Pixel_original:”, img.shape): This is a program for acquiring the attribute information of the image (the number of columns and rows, the type of image data, and the number of pixels) and the shape of the image.
Img_bw=cv2.imread(‘out_sample1.jpg’, 0): This is a program for detecting an image file saved as sample1 in CV2.
hit, wid=img_bw.shape: This is a program for reading an image file saved as sample1 in CV2.
from numpy import sum: This is a program for reading a program of numpy.

$$img\_bw \_m = np . where ( img\_bw < 1 \; 50 , 1 , 0 )$$

pyplot.imshow(img_bw_m)
print(“Rust ratio is:”, sum(img_bw_m)/(hit*wid)*100, ‘%’): These three lines are a program for cutting out a portion “darker” than the tone 150.

More specifically, the existing ratio of the concave portion is calculated by the method described in Examples using the binarized image.

The existing ratio of the concave portion in the concave-convex shape is preferably 40 to 90%, more preferably 45 to 90%, and still more preferably 50 to 90%, may be 50 to 80%, may be 50 to 70%, and may be 55 to 65%, from the viewpoint of reducing the adhesiveness between the prepregs.

The concave-convex shape is not particularly limited, and examples thereof include a needle shape, a triangular pyramid shape, a quadrangular pyramid shape, a rectangular parallelepiped shape, a spherical shape, a conical shape, a cylindrical shape, an irregular shape, and a combination thereof.

The method for forming the concave-convex shape on the surface of the prepreg is not particularly limited, and examples thereof include the following method. First, a thermosetting resin composition is applied to a support having a concave-convex shape and then dried to prepare a resin film with a support. The drying temperature and the drying time may be appropriately determined according to the content of the organic solvent in the thermosetting resin composition, the boiling point of the organic solvent, and the like, but usually, the resin film can be suitably formed by drying at preferably 50 to 200° C. (more preferably 80 to 160° C.) for about 1 to 10 minutes. In the resin film with a support, the thickness of the resin film is not particularly limited, but is preferably 1 to 100 μm, more preferably 3 to 70 μm, still more preferably 5 to 35 μm, and particularly preferably 5 to 25 μm.

Next, two sheets of the resin film with a support are prepared, and one sheet of the resin film with a support is impregnated into each of the front and back surfaces of a sheet-shaped fiber substrate described later, and then the support is peeled off and dried, so that a prepreg can be obtained. In this method, since a concave-convex shape caused by the concave-convex shape of the support is imparted to the resin film, a prepreg having a concave-convex shape on the surface is obtained by producing the prepreg using the resin film. It is also possible to adjust the concave-convex shape of the prepreg by adjusting the viscosity of the thermosetting resin composition at the time of producing the resin film with a support, adjusting the particle diameter of the inorganic filler in the resin film, or the like.

Examples of the support include a plastic film such as a polyester film and a polyolefin film; and a metal foil. Examples of the polyester film include a polyethylene terephthalate (PET) film and a polyethylene naphthalate film. Examples of the polyolefin film include a polyethylene film, a polypropylene film, and a polyvinyl chloride film. Examples of the metal foil include a copper foil and an aluminum foil. Among these, as the support, a plastic film is preferable, a polyester film is more preferable, and a PET film is more preferable.

The support having a concave-convex shape can be produced by kneading particles into the support. The concave-convex shape can be adjusted by the amount of the particles to be kneaded. The more the amount of the particles to be kneaded is, the larger the concave-convex shape tends to be, and the less the amount of the particles to be kneaded is, the smaller the concave-convex shape tends to be. From the same viewpoint, the amount of the particles to be kneaded into the support is not particularly limited, but is preferably an amount that occupies 30 to 90% of the surface of the support, more preferably an amount that occupies 60 to 90% of the surface of the support, and still more preferably an amount that occupies 80 to 90% of the surface of the support.

Examples of the particles to be kneaded into the support include particles of an inorganic filler (C) described later; particles of an organic filler; and the like. Examples of the particles of the organic filler include crosslinked NBR particles obtained by copolymerizing acrylonitrile and butadiene; a copolymer of acrylonitrile-butadiene such as a copolymer of acrylonitrile, butadiene, and a carboxylic acid such as acrylic acid; and so-called core-shell rubber particles having polybutadiene, NBR, silicone rubber, or the like as a core and an acrylic acid derivative as a shell.

In addition, as the support having a concave-convex shape, commercially available products such as U4000 which is “Toyobo Ester (registered trademark) Film” series manufactured by Toyobo Co., Ltd.; and X42 which is “Lumirror (registered trademark)” series manufactured by Toray Industries, Inc. can also be used.

As described above, the prepreg of the present embodiment includes a thermosetting resin composition containing (A) a thermosetting resin and (B) a compound having a structural unit (b1) derived from a conjugated diene compound, or a semi-cured product of the thermosetting resin composition.

The prepreg of the present embodiment is not particularly limited, but can be produced using a resin film formed from the thermosetting resin composition and a sheet-shaped fiber substrate. As described above, a resin film with a support is used as the resin film formed from the thermosetting resin composition. The prepreg of the present embodiment can be obtained by impregnating the resin film with a support into a sheet-shaped fiber substrate, followed by heating and drying, and semi-curing (B-staging) as necessary. More specifically, the prepreg of the present embodiment can be produced by impregnating the resin film with a support into the sheet-shaped fiber substrate, then peeling off the support, and then heating and drying in a drying furnace usually at 80 to 200° C. for 1 to 30 minutes and semi-curing (B-staging).

Here, in the present disclosure, B-staging is to bring into a B-stage state as defined in JIS K6900 (1994).

As the sheet-shaped fiber substrate, known ones used for various laminates for electrical insulating materials can be used. Examples of the material of the sheet-shaped fiber substrate include inorganic fibers such as glass such as E glass, D glass, S glass, and Q glass; organic fibers such as polyimide, polyester, and tetrafluoroethylene; and mixtures thereof. The sheet-shaped fiber substrate may be a woven fabric, a nonwoven fabric, a roving, a chopped strand mat, a surfacing mat, or the like. The material of the sheet-shaped fiber substrate is preferably an inorganic fiber and more preferably glass. In addition, the sheet-shaped fiber substrate is preferably a woven fabric.

The thickness of the sheet-shaped fiber substrate is not particularly limited, but may be 1 to 100 μm, may be 3 to 70 μm, or may be 5 to 35 μm.

The surface roughness (Rz) of the prepreg of the present embodiment is preferably 12.0 m or more, and may be 12.0 to 20 μm, may be 12.5 to 17 μm, or may be 12.5 to 14.5 μm from the viewpoint of reducing the adhesiveness between the prepregs. Here, the surface roughness (Rz) is a value measured by a method described in Examples which will be described later.

The surface roughness (Rz) of the prepreg corresponds to the depth of the concave-convex shape.

The thickness of the prepreg of the present embodiment may be 5 to 300 μm, may be 10 to 250 μm, may be 15 to 150 μm, may be 15 to 120 μm, may be 15 to 100 μm, may be 20 to 60 am, or may be 20 to 45 μm. The thickness of the prepreg herein means the thickness of one ply of the prepreg. In the present disclosure, the thickness of the prepreg is an average value of values obtained by measuring arbitrary five portions of the prepreg with a digimatic indicator.

### (Thermosetting Resin Composition)

Hereinafter, each component contained in the thermosetting resin composition will be described in detail in order.

### ((A) Thermosetting Resin)

Examples of the component (A) include an epoxy resin, a maleimide compound, a phenol resin, a polyimide resin, a cyanate resin, an isocyanate resin, a benzoxazine resin, an oxetane resin, an amino resin, an unsaturated polyester resin, an allyl resin, a dicyclopentadiene resin, a silicone resin, a triazine resin, and a melamine resin. Among these, the component (A) preferably contains at least one selected from the group consisting of an epoxy resin, a maleimide compound, a phenol resin, a polyimide resin, a cyanate resin, and an isocyanate resin, more preferably contains at least one selected from the group consisting of an epoxy resin and a maleimide compound, and still more preferably contains a maleimide compound from the viewpoint of low thermal expansion and the like.

The component (A) may be used alone, or in combination of two or more kinds thereof.

The epoxy resin is preferably an epoxy resin having two or more epoxy groups in one molecule. The epoxy resin herein is classified into a glycidyl ether type epoxy resin, a glycidyl amine type epoxy resin, a glycidyl ester type epoxy resin, and the like. Among these, a glycidyl ether type epoxy resin is preferable.

Epoxy resins are also classified into various epoxy resins depending on the main backbone, and in each of the above types of epoxy resins, epoxy resins are further classified into bisphenol type epoxy resins such as bisphenol A type epoxy resin, bisphenol F type epoxy resin, and bisphenol S type epoxy resin; alicyclic epoxy resins such as dicyclopentadiene type epoxy resin; aliphatic chain epoxy resins; novolac type epoxy resins such as phenol novolac type epoxy resin, cresol novolac type epoxy resin, bisphenol A novolac type epoxy resin, bisphenol F novolac type epoxy resin, phenol aralkyl novolac type epoxy resin, and biphenyl aralkyl novolac type epoxy resin; stilbene type epoxy resins; naphthalene skeleton-containing epoxy resins such as naphthol novolac type epoxy resin and naphthol aralkyl type epoxy resin; biphenyl type epoxy resins; xylylene type epoxy resins; and dihydroanthracene type epoxy resins.

The maleimide compound preferably contains at least one selected from the group consisting of a maleimide compound having one or more N-substituted maleimide groups and a derivative of the maleimide compound. The maleimide compound having one or more N-substituted maleimide groups is preferably a maleimide compound having two or more N-substituted maleimide groups, more preferably a maleimide compound having 2 to 10 N-substituted maleimide groups, still more preferably a maleimide compound having 2 to 5 N-substituted maleimide groups, and particularly preferably a maleimide compound having two N-substituted maleimide groups.

In addition, the maleimide compound having two or more N-substituted maleimide groups is preferably a compound in which nitrogen atoms of the maleimide groups are bonded to each other via an organic group.

Examples of the maleimide compound having one or more N-substituted maleimide groups include, but are particularly not limited to, an aromatic maleimide compound having one N-substituted maleimide group preferably bonded to an aromatic ring, such as N-phenylmaleimide, N-(2-methylphenyl)maleimide, N-(4-methylphenyl)maleimide, N-(2,6-dimethylphenyl)maleimide, N-(2,6-diethylphenyl)maleimide, N-(2-methoxyphenyl)maleimide, and N-benzylmaleimide; an aromatic bismaleimide compound having two N-substituted maleimide groups preferably bonded to an aromatic ring, such as 4,4′-diphenylmethane bismaleimide, bis(4-maleimidophenyl)ether, bis(4-maleimidophenyl)sulfone, 3,3′-dimethyl-5,5′-diethyl-4,4′-diphenylmethane bismaleimide, 4-methyl-1,3-phenylene bismaleimide, m-phenylene bismaleimide, 2,2-bis[4-(4-maleimidophenoxy)phenyl]propane, and an indane ring-containing aromatic bismaleimide; an aromatic polymaleimide compound having three or more N-substituted maleimide groups preferably bonded to an aromatic ring, such as polyphenylmethane maleimide and biphenyl aralkyl type maleimide; and an aliphatic maleimide compound such as N-dodecylmaleimide, N-isopropylmaleimide and N-cyclohexylmaleimide, 1,6-bismaleimide-(2,2,4-trimethyl)hexane, and a pyrophosphoric acid binder-type long chain alkyl bismaleimide. Among these, from the viewpoint of compatibility with other resins, adhesion to conductors, heat resistance, low thermal expansion, mechanical properties, and relative dielectric constant (Dk), an aromatic bismaleimide compound having two N-substituted maleimide groups preferably bonded to an aromatic ring and an aromatic polymaleimide compound having three or more N-substituted maleimide groups preferably bonded to an aromatic ring are more preferable, and an indane ring-containing aromatic bismaleimide and a biphenyl aralkyl type maleimide are still more preferable. In the present disclosure, the indane ring refers to a fused bicyclic structure of an aromatic 6-membered ring and a saturated aliphatic 5-membered ring. The indane ring-containing aromatic bismaleimide preferably has a divalent group represented by the following general formula (a1-1).

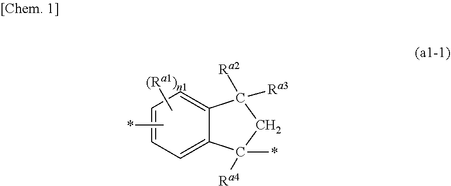

(In the formula, R^{a1} is an alkyl group having 1 to 10 carbon atoms, an alkyloxy group having 1 to 10 carbon atoms, an alkylthio group having 1 to 10 carbon atoms, an aryl group having 6 to 10 carbon atoms, an aryloxy group having 6 to 10 carbon atoms, an arylthio group having 6 to 10 carbon atoms, a cycloalkyl group having 3 to 10 carbon atoms, a halogen atom, a hydroxy group, or a mercapto group, and n1 is an integer of 0 to 3. R^{a2} to R^{a4} are each independently an alkyl group having 1 to 10 carbon atoms. * denotes a binding site.)

The indane ring-containing aromatic bismaleimide containing a divalent group represented by the general formula (a1-1) is preferably one represented by the following general formula (a1-2) from the viewpoint of relative dielectric constant (Dk), adhesion to conductors, heat resistance, and ease of production.

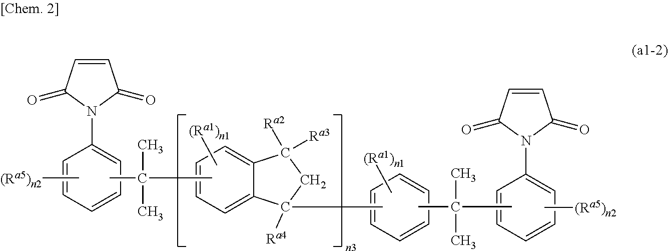

(In the formula, R^{a1} to R^{a4} and n1 are the same as in the general formula (a1-1). R^{a}s is each independently an alkyl group having 1 to 10 carbon atoms, an alkyloxy group having 1 to 10 carbon atoms, an alkylthio group having 1 to 10 carbon atoms, an aryl group having 6 to 10 carbon atoms, an aryloxy group having 6 to 10 carbon atoms, an arylthio group having 6 to 10 carbon atoms, a cycloalkyl group having 3 to 10 carbon atoms, a halogen atom, a nitro group, a hydroxy group, or a mercapto group, n2 is each independently an integer of 0 to 4, and n3 is a number from 0.95 to 10.0.)

The indane ring-containing aromatic bismaleimide represented by the general formula (a1-2) is more preferably one represented by the following general formula (a1-3), or more preferably one represented by the following general formula (a1-4), from the viewpoint of relative dielectric constant (Dk), adhesion to conductors, solubility in an organic solvent, and ease of production.

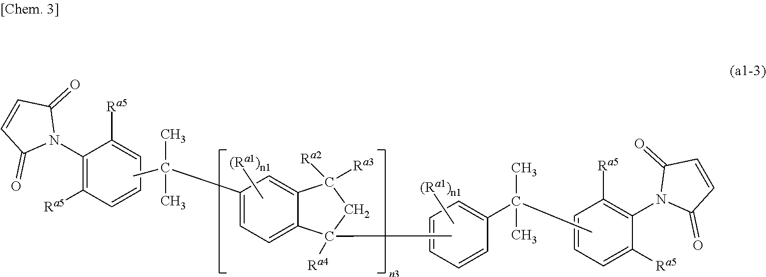

(In the formula, R^{a1} to R^{a5} and n1 and n3 are the same as in the general formula (a1-2).)

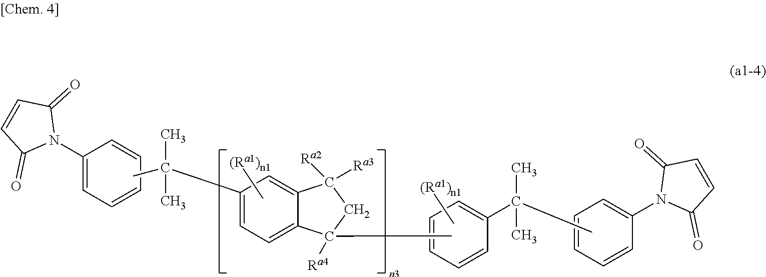

(In the formula, R^{a1} to R^{a4} and n1 and n3 are the same as in the general formula (a1-2).)

The method for producing the indane ring-containing aromatic bismaleimide is not particularly limited, and the indane ring-containing aromatic bismaleimide can be produced by using and applying a known production method.

Examples of the “derivative” of the maleimide compound include an addition reaction product of the maleimide compound having one or more (preferably two or more) N-substituted maleimide groups and an amine compound such as a monoamine compound and a diamine compound.

Examples of the monoamine compound include monoamine compounds having an acidic substituent, such as o-aminophenol, m-aminophenol, p-aminophenol, o-aminobenzoic acid, m-aminobenzoic acid, p-aminobenzoic acid, o-aminobenzenesulfonic acid, m-aminobenzenesulfonic acid, p-aminobenzenesulfonic acid, 3,5-dihydroxyaniline, and 3,5-dicarboxyaniline.

Examples of the diamine compound include aromatic diamine compounds such as 4,4′-diaminodiphenylmethane, 4,4′-diaminodiphenylethane, 4,4′-diaminodiphenylpropane, 2,2′-bis(4,4′-diaminodiphenyl)propane, 3,3′-dimethyl-4,4′-diaminodiphenylmethane, 3,3′-diethyl-4,4′-diaminodiphenylmethane, 3,3′-dimethyl-4,4′-diaminodiphenylethane, 3,3′-diethyl-4,4′-diaminodiphenylethane, 4,4′-diaminodiphenyl ether, 4,4′-diaminodiphenyl thioether, 3,3′-dihydroxy-4,4′-diaminodiphenylmethane, 2,2′,6,6′-tetramethyl-4,4′-diaminodiphenylmethane, 3,3′-dichloro-4,4′-diaminodiphenylmethane, 3,3′-dibromo-4,4′-diaminodiphenylmethane, 2,2′,6,6′-tetrachloro-4,4′-diaminodiphenylmethane, 2,2′,6,6′-tetrabromo-4,4′-diaminodiphenylmethane, and siloxane diamine.

### (Content of Component (A))

The content of the thermosetting resin (A) in the thermosetting resin composition in the prepreg of the present embodiment is not particularly limited, but is preferably 5 to 95% by mass, more preferably 30 to 95% by mass, still more preferably 50 to 95% by mass, particularly preferably 60 to 95% by mass, and most preferably 70 to 90% by mass, with respect to the total sum of the resin components in the thermosetting resin composition, from the viewpoint of heat resistance and moldability.

((B) Compound Having Structural Unit (b1) Derived from Conjugated Diene Compound)

From the viewpoint of relative dielectric constant (Dk) in a high frequency band equal to or higher than 10 GHz band [hereinafter, simply referred to as “relative dielectric constant (Dk)” ], the thermosetting resin composition in the prepreg of the present embodiment or the cured product thereof contains a compound having a structural unit (b1) derived from a conjugated diene compound as the component (B).

In the structural unit (b1) derived from a conjugated diene compound, from the viewpoint of the relative dielectric constant (Dk), the conjugated diene compound is preferably at least one selected from the group consisting of butadiene and isoprene, more preferably contains butadiene, and still more preferably is butadiene.

The structural unit (b1) derived from a conjugated diene compound may be a 1,2-bond unit of butadiene, a 1,4-bond unit of butadiene, a 3,4-bond unit of isoprene, a 1,4-bond unit of isoprene, or a bond unit in which these bond units are hydrogenated. Here, specific examples of the bond unit in which these bond units are hydrogenated include, as shown in the following structural formula, a “butylene unit” in which a 1,2-bond unit of butadiene is a hydrogenated bond unit, an “ethylene unit” in which a 1,4-bond unit of butadiene is a hydrogenated bond unit (generally, referred to in this way by paying attention to the structural unit surrounded by parentheses in the following structural formula; in addition, the parentheses are given for explanation and are not intended to separate the structural units), an “ethylene-butylene unit” having both the butylene unit and the ethylene unit, an “isopentene unit” (“3-methyl-1-butene unit”) in which a 3,4-bond unit of isoprene is a hydrogenated bond unit, an “ethylene-propylene unit” in which a 1,4-bond unit of isoprene is a hydrogenated bond unit (generally, referred to in this way by paying attention to the structural unit surrounded by parentheses in the following structural formula; in addition, the parentheses are given for explanation and are not intended to separate the structural units), and the like (see the following structural formula).

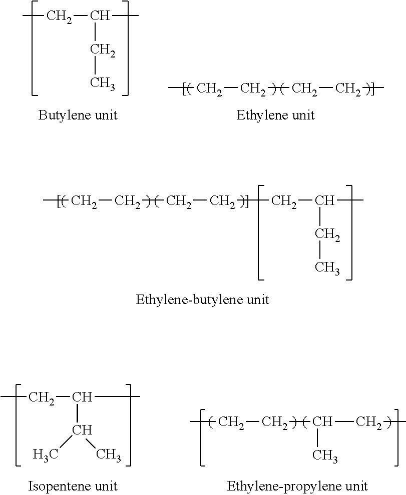

The structural unit (b1) derived from a conjugated diene compound is preferably a butylene unit, an ethylene unit, or an ethylene-butylene unit, more preferably an ethylene-butylene unit, from the viewpoint of relative dielectric constant (Dk).

Specific examples of the conjugated diene compound include 1,3-butadiene, isoprene, 1,3-pentadiene, 2,3-dimethyl-1,3-butadiene, 2-phenyl-1,3-butadiene, and 1,3-hexadiene. Among these, as the conjugated diene compound, 1,3-butadiene and isoprene are preferable, and 1,3-butadiene is more preferable.

As the component (B), it is preferable to include a “compound having a structural unit (b1) derived from a conjugated diene compound and a structural unit (b2) derived from an aromatic vinyl compound”. By having the structural unit (b2) in addition to the structural unit (b1), non-adhesiveness between prepregs tends to be further improved.

In the compound having a structural unit (b1) derived from a conjugated diene compound and a structural unit (b2) derived from an aromatic vinyl compound, the content ratio [(b1)/(b2)] of each structural unit is preferably 97/3 to 50/50, more preferably 95/5 to 55/45, still more preferably 92/8 to 60/40, and particularly preferably 90/10 to 65/35, and may be 97/3 to 80/20 or may be 85/15 to 60/40, on a mass basis, from the viewpoint of a relative dielectric constant (Dk) and a decrease in adhesiveness between prepregs.

When the content ratio of the structural unit (b1) derived from a conjugated diene compound is increased, the relative dielectric constant (Dk) tends to be excellent, and when the content ratio of the structural unit (b2) derived from an aromatic vinyl compound is increased, the adhesiveness between prepregs tends to be decreased.

In the structural unit (b2), examples of the aromatic vinyl compound include styrene, α-methylstyrene, 2,4-dimethylstyrene, 1-vinylnaphthalene, 4-methoxystyrene, monochlorostyrene, and divinylbenzene. Among these, styrene is preferable.

Specific examples of the compound having the structural unit (b1) derived from a conjugated diene compound and the structural unit (b2) derived from an aromatic vinyl compound include styrene-based thermoplastic elastomers such as a styrene-butadiene-styrene block copolymer (SBS), a hydride of a styrene-butadiene-styrene block copolymer (for example, SEBS or SBBS), a styrene-isoprene-styrene block copolymer (SIS), a hydride of a styrene-isoprene-styrene block copolymer (SEPS), and a hydride of a styrene-(isoprene and butadiene)-styrene block copolymer (SEEPS). Among these, SEBS and SEPS are preferable, and SEBS is more preferable from the viewpoint of the relative dielectric constant (Dk), the non-adhesiveness between prepregs, the crack resistance, and the like. Here, the SEBS is obtained by hydrogenating the entire butadiene unit of a styrene-butadiene-styrene block copolymer (SBS) and is named by taking the initial letters of each of styrene-ethylene-butylene-styrene, and the SBBS is obtained by selectively hydrogenating the 1,2-bond unit in the butadiene unit of the styrene-butadiene-styrene block copolymer (SBS) and is named by taking the initial letters of each of styrene-(1,4-butadiene)-butylene-styrene.

In the compound having the structural unit (b1) derived from a conjugated diene compound and the structural unit (b2) derived from an aromatic vinyl compound, a hydrogenation rate is preferably 70 mol % or more, more preferably 80 mol % or more, still more preferably 90 mol % or more, and particularly preferably 95 mol % or more. The upper limit of the hydrogenation rate is not particularly limited and may be 100 mol % or less or may be 99 mol % or less. That is, the hydrogenation rate may be 70 to 100 mol %.

The compound having the structural unit (b1) derived from a conjugated diene compound and the structural unit (b2) derived from an aromatic vinyl compound may be modified with an acid anhydride such as maleic anhydride, and examples thereof include SEBS modified with an acid anhydride such as maleic anhydride and SEPS modified with an acid anhydride such as maleic anhydride. The acid value of the acid-modified “compound having a structural unit (b1) derived from a conjugated diene compound and a structural unit (b2) derived from an aromatic vinyl compound” is not particularly limited, but is preferably 2 to 20 mgCH₃ONa/g, more preferably 5 to 15 mgCH₃ONa/g, and still more preferably 7 to 13 mgCH₃ONa/g. The acid value can be obtained by a titration method using sodium methoxide.

The content of the “compound having a structural unit (b1) derived from a conjugated diene compound and a structural unit (b2) derived from an aromatic vinyl compound” in the component (B) is not particularly limited, and may be 20% by mass or more, may be 40% by mass or more, may be 50% by mass or more, may be 80% by mass or more, may be 90% by mass or more, may be 95% by mass or more, may be 98% by mass or more, or may be 100% by mass.

The weight-average molecular weight (Mw) of the component (B) is not particularly limited, but is preferably 12,000 to 1,000,000, more preferably 30,000 to 500,000, and still more preferably 50,000 to 250,000. The weight-average molecular weight (Mw) may be 50,000 to 100,000, may be 130,000 to 250,000, or may be 150,000 to 200,000.

In the present disclosure, the weight-average molecular weight (Mw) is a value measured by gel permeation chromatography (GPC) in terms of polystyrene, and specifically, a value measured by a method described in Examples.

### (Content of Component (B))

When the thermosetting resin composition in the prepreg of the present embodiment contains the component (B), the content thereof is not particularly limited, but is preferably 1% by mass or more and less than 14% by mass, more preferably 1 to 13% by mass, still more preferably 3 to 12% by mass, and may be 5 to 12% by mass, may be 6.5 to 11.5% by mass, may be 6.5 to 9.5% by mass, may be 8 to 11.5% by mass, or may be 1 to 8% by mass, may be 3 to 8% by mass, or may be 5 to 8% by mass, with respect to the total sum of the resin components in the thermosetting resin composition, from the viewpoint of the relative dielectric constant (Dk), the reduction in adhesiveness between prepregs, and the compatibility.

When the content of the component (B) is equal to or more than the lower limit value, an excellent relative dielectric constant (Dk) tends to be obtained, and when it is equal to or less than the upper limit value, an increase in the adhesiveness between prepregs tends to be suppressed or reduced, and further, good heat resistance, moldability, processability and flame retardancy tend to be obtained.

### (Inorganic Filler (C))

When the thermosetting resin composition in the prepreg of the present embodiment contains (C) an inorganic filler [hereinafter sometimes referred to as component (C)], the low thermal expansion coefficient, heat resistance, and flame retardancy tend to be improved.

Examples of the component (C) include, but are not limited to, silica, alumina, titanium oxide, mica, beryllia, barium titanate, potassium titanate, strontium titanate, calcium titanate, aluminum carbonate, magnesium hydroxide, aluminum hydroxide, aluminum silicate, calcium carbonate, calcium silicate, magnesium silicate, silicon nitride, boron nitride, clay (baked clay, and the like), a molybdic acid compound such as zinc molybdate, talc, aluminum borate, and silicon carbide. The component (C) may be used alone or in combination of two or more kinds thereof. Among these, silica, alumina, mica, and talc are preferable, silica and alumina are more preferable, and silica is still more preferable, from the viewpoint of thermal expansion coefficient, heat resistance, and flame retardancy. Examples of silica include crushed silica, fumed silica, and fused silica (fused spherical silica).

The shape and particle size of the component (C) are not particularly limited, but the particle diameter is preferably 0.01 to 20 μm, more preferably 0.1 to 10 μm, still more preferably 0.2 to 1 μm, and particularly preferably 0.3 to 0.8 km. Here, the particle diameter refers to an average particle diameter, and refers to a particle diameter at a point corresponding to a volume of 50% when a cumulative frequency distribution curve according to the particle diameter is obtained by setting the total volume of the particles to 100%. The particle diameter of the component (C) can be measured by a particle size distribution measuring device or the like using a laser diffraction scattering method.

### (Content of Component (C))

When the thermosetting resin composition in the prepreg of the present embodiment contains the component (C), the content of the component (C) in the thermosetting resin composition is not particularly limited, but is preferably 1 to 70% by volume, more preferably 5 to 60% by volume, still more preferably 10 to 50% by volume, and may be 10 to 35% by volume, may be 10 to 25% by volume, or may be 25 to 50% by volume, may be 30 to 45% by volume, may be 1 to 50% by volume, or may be 1 to 30% by volume, with respect to the total sum of solid contents of the thermosetting resin composition, from the viewpoint of reducing the adhesiveness between prepregs, and the thermal expansion coefficient, the heat resistance, and the flame retardancy.

In addition, since the content of the component (C) is equal to or less than the upper limit value, the relative dielectric constant (Dk) tends to be decreased. However, when the content of the component (C) is suppressed to be small, the adhesiveness between prepregs tends to be increased. Therefore, in this case, the effect of the present embodiment due to the existing ratio of the concave portion in the concave-convex shape being 30 to 90%, that is, the effect of reducing the adhesiveness between prepregs has a further large influence. The effect tends to be remarkable in a case where the upper limit value of the content of the component (C) is 50% by volume or less, and further 30% by volume or less with respect to the total sum of solid contents.

In addition, when the component (C) is used, for the purpose of improving the dispersibility of the component (C) and the adhesiveness between the component (C) and organic components in the thermosetting resin composition, a coupling agent may be used in combination as needed. The coupling agent is not particularly limited, and for example, a silane coupling agent or a titanate coupling agent can be appropriately selected and used. These coupling agents may be used alone or in combination of two or more kinds thereof. In addition, the amount of the coupling agent used is not particularly limited.

In the case of using the coupling agent, a so-called integral blend treatment method in which the coupling agent is added after the component (C) is blended in the thermosetting resin composition may be used, but a method in which an inorganic filler surface-treated with the coupling agent by a dry or wet method in advance is used is preferable. By adopting this method, the characteristics of the component (C) can be more effectively exhibited.

When the component (C) is used in the present embodiment, for the purpose of improving the dispersibility of the component (C) in the thermosetting resin composition, if necessary, the component (C) can be used as a slurry in which the component (C) is dispersed in an organic solvent in advance. Examples of the organic solvent include the same organic solvents as described later.

### ((D) Compatibilizer)

The thermosetting resin composition in the prepreg of the present embodiment may further contain (D) a compatibilizer [hereinafter, sometimes referred to as component (D)]. When the thermosetting resin composition contains the component (D), the compatibility between the component (A) and the component (B) is enhanced, and the relative dielectric constant (Dk) tends to be further reduced.

The compatibilizer (D) is not particularly limited as long as it is a compound for enhancing the compatibility between the component (A) and the component (B). For example, when the component (A) contains a maleimide compound and the component (B) contains a “compound having a structural unit (b1) derived from a conjugated diene compound and a structural unit (b2) derived from an aromatic vinyl compound”, polyphenylene ether, modified polyphenylene ether, a conjugated diene polymer, a modified conjugated diene polymer, or the like can be used as the component (D). Examples of the modified polyphenylene ether include a compound obtained by introducing a functional group into polyphenylene ether. Examples of the functional group include an amino group, an epoxy group, a carboxy group, a styryl group, an acrylic group, and a methacrylic group. Among these, from the viewpoint of the relative dielectric constant (Dk) and the compatibility, an acrylic group and a methacrylic group are preferable, and a methacrylic group is more preferable. That is, the modified polyphenylene ether is preferably a methacrylic-modified polyphenylene ether. The modified polyphenylene ether may have the functional group at an end of the polymer chain or inside the polymer chain. The modified polyphenylene ether preferably has the functional group at an end of the polymer chain, and more preferably has the functional group at both ends of the polymer chain.

The weight-average molecular weight (Mw) of the polyphenylene ether and the modified polyphenylene ether is not particularly limited, but is preferably 1,000 to 25,000. When the weight-average molecular weight of the polyphenylene ether and the modified polyphenylene ether is 1,000 or more, the relative dielectric constant (Dk) tends to be further improved. In addition, when the weight-average molecular weight of the polyphenylene ether and the modified polyphenylene ether is 25,000 or less, the compatibility of the thermosetting resin composition is further improved, and the thermosetting resin composition becomes difficult to be separated even after being left for a long period of time, that is, the storage stability tends to be increased. From the same viewpoint, the weight-average molecular weight of the polyphenylene ether and the modified polyphenylene ether is more preferably 1,000 to 20,000, still more preferably 1,000 to 15,000, yet still more preferably 1,200 to 10,000, particularly preferably 1,200 to 5,000, and most preferably 1,200 to 3,000.

Examples of the conjugated diene compound which is a monomer component of the conjugated diene polymer include 1,3-butadiene, isoprene, 1,3-pentadiene, 2,3-dimethyl-1,3-butadiene, 2-phenyl-1,3-butadiene, and 1,3-hexadiene.

The conjugated diene polymer may be a polymer of one conjugated diene compound or a copolymer of two or more conjugated diene compounds.

The conjugated diene polymer is preferably a conjugated diene polymer having a vinyl group in a side chain from the viewpoint of compatibility with other resins and relative dielectric constant (Dk).

The number of side-chain vinyl groups in one molecule of the conjugated diene polymer is not particularly limited, but is preferably 2 or more, more preferably 5 or more, and still more preferably 10 or more from the viewpoint of compatibility with other resins and relative dielectric constant (Dk).

The upper limit of the number of side-chain vinyl groups in one molecule of the conjugated diene polymer is not particularly limited, but for example, may be 100 or less, may be 80 or less, or may be 60 or less.

Examples of the conjugated diene polymer include polybutadiene having a vinyl group and polyisoprene having a vinyl group. Among these, from the viewpoint of relative dielectric constant (Dk) and heat resistance, polybutadiene having a vinyl group is preferable, and polybutadiene having a 1,2-vinyl group derived from 1,3-butadiene is more preferable. As the polybutadiene having a 1,2-vinyl group derived from 1,3-butadiene, a polybutadiene homopolymer having a 1,2-vinyl group derived from 1,3-butadiene is preferable.

The 1,2-vinyl group derived from 1,3-butadiene contained in the conjugated diene polymer is a vinyl group contained in a structural unit represented by the following formula (d1).

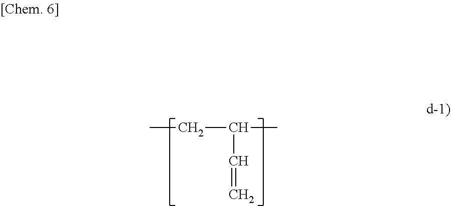

When the conjugated diene polymer is polybutadiene having a 1,2-vinyl group, the content of the structural unit having a 1,2-vinyl group (hereinafter, sometimes referred to as “vinyl group content”) based on the total structural units derived from butadiene constituting the polybutadiene is not particularly limited, but is preferably 50 mol % or more, more preferably 70 mol % or more, and still more preferably 85 mol % or more, from the viewpoint of compatibility with other resins, relative dielectric constant (Dk), and heat resistance. The upper limit of the vinyl group content is not particularly limited, and may be 100 mol % or less, may be 95 mol % or less, or may be 90 mol % or less. The structural unit having a 1,2-vinyl group is preferably a structural unit represented by the above formula (d1).

From the same viewpoint, the polybutadiene having a 1,2-vinyl group is preferably a 1,2-polybutadiene homopolymer.

The number-average molecular weight (Mn) of the conjugated diene polymer is not particularly limited, but is preferably 400 to 3,000, more preferably 600 to 2,000, and still more preferably 800 to 1,500, from the viewpoint of compatibility with other resins, relative dielectric constant (Dk), and heat resistance. In the present disclosure, the number-average molecular weight (Mn) is a value measured by gel permeation chromatography (GPC) in terms of polystyrene, and specifically, a value measured by a method described in Examples.

A modified conjugated diene polymer is a polymer obtained by modifying the conjugated diene polymer.

When the resin composition of the present embodiment contains a modified conjugated diene polymer, excellent relative dielectric constant (Dk) tends to be easily obtained while having good heat resistance and low thermal expansion.

As the modified conjugated diene polymer, a modified conjugated diene polymer obtained by modifying a conjugated diene polymer having a vinyl group in a side chain with a maleimide compound having two or more N-substituted maleimide groups is preferred from the viewpoint of compatibility with other resins, relative dielectric constant (Dk), and adhesion to conductors.

As the conjugated diene polymer having a vinyl group in a side chain, for example, those described in the above description of the conjugated diene polymer can be used, and preferred embodiments thereof are also the same.

The conjugated diene polymer having a vinyl group in a side chain may be used alone or may be used in combination of two or more kinds thereof.

As the maleimide compound having two or more N-substituted maleimide groups, for example, the maleimide compounds having two or more N-substituted maleimide groups in the description of the maleimide compound in the component (A) can be used, and preferred embodiments thereof are also the same.

Examples of the maleimide compound having two or more N-substituted maleimide groups include aliphatic hydrocarbon group-containing maleimide such as N,N′-ethylenebismaleimide, N,N′-hexamethylene bismaleimide, bis(4-maleimidocyclohexyl)methane, and 1,4-bis(maleimidomethyl)cyclohexane; and aromatic hydrocarbon group-containing maleimide such as N,N′-(1,3-phenylene)bismaleimide, N,N′-[1,3-(2-methylphenylene)]bismaleimide, N,N′-[1,3-(4-methylphenylene)]bismaleimide, N,N′-(1, 4-phenylene)bismaleimide, bis(4-maleimidophenyl)methane, bis(3-methyl-4-maleimidophenyl)methane, 3,3′-dimethyl-5,5′-diethyl-4,4′-diphenylmethane bismaleimide, bis(4-maleimidophenyl) ether, bis(4-maleimidophenyl) sulfone, bis(4-maleimidophenyl) sulfide, bis(4-maleimidophenyl) ketone, 1,3-bis(4-maleimidophenoxy)benzene, bis[4-(3-maleimidophenoxy)phenyl]methane, 2,2-bis[4-(3-maleimidophenoxy)phenyl]propane, 2,2-bis[4-(4-maleimidophenoxy)phenyl]propane, 2,2-bis[4-(3-maleimidophenoxy)phenyl]-1,1,1,3,3,3-hexafluoropropane, 1,4-bis[4-(4-maleimidophenoxy)-α,α-dimethylbenzyl]benzene, and polyphenylmethane maleimide. Among these, 3,3′-dimethyl-5,5′-diethyl-4,4′-diphenylmethane bismaleimide is more preferable.

The maleimide compound having two or more N-substituted maleimide groups may be used alone or may be used in combination of two or more kinds thereof.

The modified conjugated diene polymer preferably has, in a side chain, a substituent formed by a reaction between a side-chain vinyl group of a conjugated diene polymer having a vinyl group in a side chain and an N-substituted maleimide group of a maleimide compound having two or more N-substituted maleimide groups [hereinafter, sometimes referred to as a “maleimide compound-derived substituent” ].

The maleimide compound-derived substituent is preferably a group containing a structure represented by the following general formula (d2) or (d3) as a structure derived from a maleimide compound having two or more N-substituted maleimide groups, from the viewpoint of compatibility with other resins, relative dielectric constant (Dk), low thermal expansion, and heat resistance.

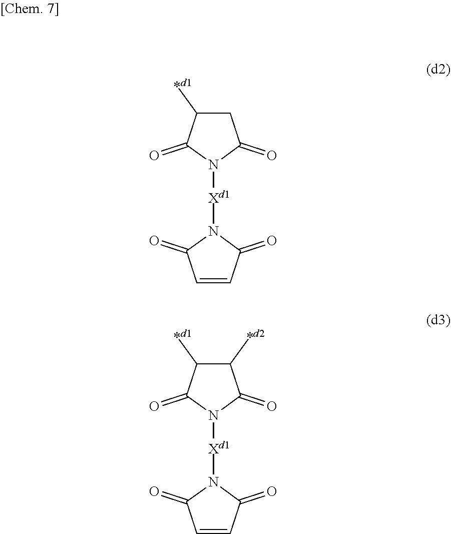

(In the formula, X^{d1} is a divalent group obtained by removing two N-substituted maleimide groups from a maleimide compound having two or more N-substituted maleimide groups, *^{d1} is a site bonded to a carbon atom derived from a side-chain vinyl group of a conjugated diene polymer having a vinyl group in a side chain, and *^{d2} is a site bonded to another atom.)

The modified conjugated diene polymer preferably has a maleimide compound-derived substituent and a vinyl group in a side chain.

The vinyl group contained in the modified conjugated diene polymer is preferably a 1,2-vinyl group derived from 1,3-butadiene.

The number-average molecular weight (Mn) of the modified conjugated diene polymer is not particularly limited, but is preferably 700 to 6,000, more preferably 800 to 5,000, and still more preferably 1,000 to 2,500, from the viewpoint of compatibility with other resins, relative dielectric constant (Dk), low thermal expansion, and heat resistance.

The modified conjugated diene polymer can be produced by reacting a conjugated diene polymer having a vinyl group in a side chain with a maleimide compound having two or more N-substituted maleimide groups.

The method for reacting the conjugated diene polymer having a vinyl group in a side chain with the maleimide compound having two or more N-substituted maleimide groups is not particularly limited. For example, a conjugated diene polymer having a vinyl group in a side chain, a maleimide compound having two or more N-substituted maleimide groups, a reaction catalyst, and an organic solvent are charged into a reaction vessel, and the mixture is reacted while, as necessary, heating, keeping warm, and stirring to obtain a modified conjugated diene polymer.

The ratio (Mₘ/Mᵥ) of the number of moles (Mₘ) of the N-substituted maleimide group of the maleimide compound having two or more N-substituted maleimide groups to the number of moles (Mᵥ) of the side-chain vinyl group of the conjugated diene polymer having a vinyl group in a side chain during the reaction is not particularly limited, but is preferably 0.001 to 0.5, more preferably 0.005 to 0.1, and still more preferably 0.008 to 0.05 from the viewpoint of compatibility with other resins of the resulting modified conjugated diene polymer and suppression of gelation of the product during the reaction.

### (Content of Component (D))

In a case where the thermosetting resin composition in the prepreg of the present embodiment contains the component (D), the content of the component (D) in the thermosetting resin composition is not particularly limited, but is preferably 1 to 40% by mass, more preferably 3 to 30% by mass, still more preferably 5 to 25% by mass, particularly preferably 5 to 20% by mass, and most preferably 5 to 15% by mass, with respect to the total sum of the resin components in the thermosetting resin composition, from the viewpoint of relative dielectric constant (Dk) and compatibility. When the content of the component (D) is equal to or more than the lower limit value, relative dielectric constant (Dk) and compatibility tend to be good. When the content of the component (D) is equal to or less than the upper limit value, heat resistance, moldability, and processability tend to be good.

### (Curing Accelerator (E))

The thermosetting resin composition in the prepreg of the present embodiment may further contain (E) a curing accelerator [hereinafter, sometimes referred to as component (E)].

Examples of the component (E) include amine-based curing accelerators, imidazole-based curing accelerators, phosphorus-based curing accelerators, organometallic salts, acidic catalysts, and organic peroxides. In the present disclosure, imidazole-based curing accelerators are not classified as amine-based curing accelerators. These curing accelerators may be used alone or in combination of two or more kinds thereof. The curing accelerator preferably includes at least one selected from the group consisting of imidazole-based curing accelerators and organic peroxides.

Examples of the imidazole-based curing accelerator include an imidazole compound such as methylimidazole, phenylimidazole, and 2-undecylimidazole; and isocyanate mask imidazole such as an addition reaction product of a hexamethylene diisocyanate resin and 2-ethyl-4-methylimidazole.

Examples of the organic peroxide include dicumyl peroxide, 2,5-dimethyl-2,5-bis(t-butylperoxy)hexyne-3, 2,5-dimethyl-2,5-bis(t-butylperoxy)hexane, t-butylperoxyisopropyl monocarbonate, α,α′-bis(t-butylperoxy)diisopropylbenzene.

### (Content of Curing Accelerator (E))

In a case where the thermosetting resin composition in the prepreg of the present embodiment contains the component (E), the content of the component (E) is not particularly limited, but in any case, the content is preferably 0.01 to 5 parts by mass, more preferably 0.05 to 4 parts by mass, still more preferably 0.1 to 3.5 parts by mass, and particularly preferably 0.3 to 2.5 parts by mass with respect to 100 parts by mass of the component (A) in the thermosetting resin composition. When the content of the curing accelerator (E) is within the above range, better heat resistance, storage stability, and moldability tend to be obtained.

### (Other Components)

The thermosetting resin composition in the prepreg of the present embodiment preferably further contains, as other components, one or more selected from the group consisting of a flame retardant, a flame retardant aid, an antioxidant, an adhesion improver, a heat stabilizer, an antistatic agent, an ultraviolet absorber, a pigment, a colorant, and a lubricant. In addition, the thermosetting resin composition may contain components other than the above-described components.

In a case where the thermosetting resin composition contains these other components (a flame retardant, a flame retardant aid, an antioxidant, an adhesion improver, a heat stabilizer, an antistatic agent, an ultraviolet absorber, a pigment, a colorant, a lubricant, and components other than these), the content of each component is not particularly limited, but for example, may be 0.01% by mass or more, and may be 10% by mass or less, may be 5% by mass or less, or may be 1% by mass or less, with respect to the total sum of the resin components in the thermosetting resin composition. The thermosetting resin composition may not contain the other components.

### (Organic Solvent)

From the viewpoint of ease of handling and ease of production of the resin film, the thermosetting resin composition may be made into a so-called “varnish” containing an organic solvent, and then the resin film may be produced.

Examples of the organic solvent include, but are not particularly limited to, alcohol-based solvents such as ethanol, propanol, butanol, methyl cellosolve, butyl cellosolve, and propylene glycol monomethyl ether; ketone-based solvents such as acetone, methyl ethyl ketone, methyl isobutyl ketone, and cyclohexanone; ether-based solvents such as tetrahydrofuran; aromatic solvents such as toluene, xylene, and mesitylene; nitrogen atom-containing solvents such as dimethylformamide, dimethylacetamide, and N-methylpyrrolidone; sulfur atom-containing solvents such as dimethyl sulfoxide; and ester-based solvents such as γ-butyrolactone. From the viewpoint of solubility, ketone-based solvents are preferable, and methyl ethyl ketone is more preferable. These organic solvents may be used alone or in combination of two or more kinds thereof.

In a case where the thermosetting resin composition is used as a varnish, the solid concentration is set to preferably 30 to 90% by mass, more preferably 40 to 80% by mass, and still more preferably 45 to 60% by mass. When the solid concentration of the thermosetting resin composition is within the above range, there is a tendency that the handling property of the thermosetting resin composition becomes easy, the coating property at the time of forming a resin film becomes good, and the appearance of the prepreg also becomes good.

The thermosetting resin composition can be produced by mixing the component (A), the component (B), and the components that can be used as necessary by a known method. At this time, the respective components may be dissolved or dispersed in the organic solvent while stirring. Conditions such as mixing order, temperature, and time are not particularly limited, and can be arbitrarily set.

### [Laminate]

The laminate of the present embodiment is a laminate having a cured product of the prepreg of the present embodiment and a metal foil.

The laminate of the present embodiment can be produced, for example, by disposing a metal foil on one or both sides of one ply of the prepreg of the present embodiment, or by disposing a metal foil on one or both sides of a laminate obtained by stacking two or more plies of the prepreg of the present embodiment, followed by heat and pressure molding. In the laminate obtained by the production method, the prepreg of the present embodiment is C-staged. In the present disclosure, C-staging is to bring into a C-stage state as defined in JIS K6900 (1994). The laminate having a metal foil may also be referred to as a metal-clad laminate.

The metal of the metal foil is not particularly limited, but from the viewpoint of conductivity, the metal may be copper, gold, silver, nickel, platinum, molybdenum, ruthenium, aluminum, tungsten, iron, titanium, chromium, or an alloy containing one or more of these metallic elements, and is preferably copper or aluminum, more preferably copper.

The method for implementing heat and pressure molding is not particularly limited, but can be implemented under conditions of a temperature of 100 to 300° C., a pressure of 0.2 to 10 MPa, and a time of 0.1 to 5 hours, for example. In addition, as the heat and pressure molding, a method of maintaining a vacuum state for 0.5 to 5 hours using a vacuum press or the like can be adopted.

### [Printed Wiring Board]

The printed wiring board of the present embodiment has a cured product of the prepreg of the present embodiment. It can also be said that the printed wiring board of the present embodiment has one or more selected from the group consisting of a cured product of the prepreg of the present embodiment and the laminate of the present embodiment.

The printed wiring board of the present embodiment can be produced by using one or more selected from the group consisting of the prepreg of the present embodiment and the laminate of the present embodiment, and performing circuit formation processing by drilling, metal plating, or etching of a metal foil by a known method, and the like. In addition, a multilayer printed wiring board can also be produced by further performing a multilayer adhesion process as necessary. In the printed wiring board of the present embodiment, the prepreg of the present embodiment is C-staged.

### [Semiconductor Package]

The semiconductor package of the present embodiment is a semiconductor package including the printed wiring board of the present embodiment and a semiconductor element. The semiconductor package of the present embodiment can be produced by mounting a semiconductor element such as a semiconductor chip or a memory at a predetermined position of the printed wiring board of the present embodiment by a known method, and then sealing the semiconductor element with a sealing resin or the like.

The prepreg, the laminate, the printed wiring board, and the semiconductor package of the present embodiment can be suitably used in an electronic device that handles a high-frequency signal of 10 GHz or more. In particular, the printed wiring board is useful as a printed wiring board for millimeter-wave radar.

### EXAMPLES

Hereinafter, the present embodiment will be specifically described with reference to Examples. However, the present embodiment is not limited to the following Examples.

In each example, the number-average molecular weight (Mn) and the weight-average molecular weight (Mw) were measured by the following method.

### (Measurement Method of Number-Average Molecular Weight (Mn) and Weight-Average Molecular Weight (Mw))

It was converted from a calibration curve using standard polystyrene by gel permeation chromatography (GPC). The calibration curve was approximated by a cubic equation using standard polystyrene: TSK standard POLYSTYRENE (Type; A-2500, A-5000, F-1, F-2, F-4, F-10, F-20, F-40) (manufactured by Tosoh Corporation, trade name). The measurement conditions of GPC are shown below.

### Device:

Pump: L-6200 type (manufactured by Hitachi High-Tech Corporation)
Detector: L-3300 type RI (manufactured by Hitachi High-Tech Corporation)
Column oven: L-655A-52 (manufactured by Hitachi High-Tech Corporation)
Column: Guard column; TSK Guardcolumn HHR-L+column; TSKgel G40001HHR+TSKgel G20001HHR (all manufactured by Tosoh Corporation, trade name)
Column size: 6.0×40 mm (guard column), 7.8×300 mm (column)
Eluent: tetrahydrofuran
Sample concentration: 30 mg/5 mL
Injection amount: 20 μL
Flow rate: 1.00 mL/min
Measurement temperature: 40° C.

In addition, each evaluation and each measurement method in each example are shown below.

### [Evaluation and Measurement Method]

### (1. Existing Ratio of Concave Portion in Concave-Convex Shape of Prepreg Surface)

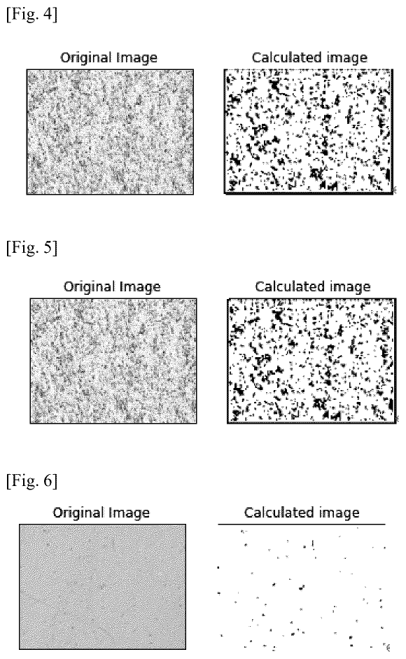

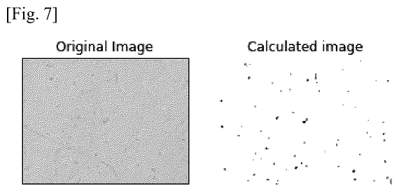

Regarding the existing ratio of the concave portion in the concave-convex shape of the prepreg surface prepared in each example, a range of 524.2 μm×669.2 μm at the center of the prepreg surface was observed with a scanning electron microscope (SEM), and an SEM image (magnification: 100 times) was obtained. A binarized image of the SEM image was obtained by setting a program shown in FIG. 1 using a programming language “Python” for the SEM image. Next, the existing ratio of white and black in the binarized image was determined, and the existing ratio of black was defined as the existing ratio of the concave portion in the concave-convex shape of the prepreg surface. The obtained SEM images are shown on the left side of FIG. 2 to FIG. 7, and the binarized images are shown on the right side of FIG. 2 to FIG. 7.

### (2. Surface Roughness (Rz) of Prepreg)

The surface roughness (Rz) of the prepreg produced in each example was measured. The details are as follows.

First, a reference length was extracted from the roughness curve in the direction of the average line thereof. In this extracted portion, with the average line as a reference, the sum of the average value of the absolute values of the elevations of the highest to fifth highest peaks and the average value of the absolute values of the elevations of the lowest to fifth lowest valleys was determined, and this value was calculated as Rz expressed in micrometers (m). For the measurement of Rz, a shape analysis laser microscope “VK-X250” (manufactured by Keyence Corporation) was used.

(3. Adhesiveness between Prepregs)

Fifteen plies of the prepreg produced in each example were stacked and placed in an aluminum-deposited pack, and allowed to stand for one week in a state of being pressure-bonded at 1 MPa, and then the pressure bonding was released. Then, the adhesion was evaluated according to the following evaluation criteria.
A: The prepreg can be easily peeled off by hand.
B: When the prepreg is peeled off by hand, a crack occurs in a part of the prepreg.
C: The stacked prepregs are integrated and cannot be peeled off by hand.

### (4. Relative Dielectric Constant (Dk))

The outer layer copper foil of the double-sided copper-clad laminate obtained in each example was removed by immersing in a copper etching solution (10% by mass solution of ammonium persulfate, manufactured by Mitsubishi Gas Chemical Company, Inc.) and then cut out to a length of 60 mm and a width of 2 mm, which was used as a test piece. The relative dielectric constant (Dk) was measured by a cavity resonator perturbation method using the test piece. A vector type network analyzer “N5222B” manufactured by Agilent Technologies, Inc. was used as a measurement instrument, a cavity resonator “CP129” (10 GHz band resonator) manufactured by Kanto Electronics Application & Development Inc. was used as a cavity resonator, and a measurement program “CPMA-V2” was used as a measurement program. The measurement was performed under conditions of a frequency of 10 GHz and a measurement temperature of 25° C.

### Production Example 1 [Production of Modified Conjugated Diene Polymer (for Component (D))]

100 parts by mass of 1,2-polybutadiene homopolymer (number-average molecular weight (Mn)=1,200, vinyl group content=85% or more), 4.4 parts by mass of an indane ring-containing aromatic bismaleimide, 0.1 parts by mass of α,α′-bis(t-butylperoxy)diisopropylbenzene, and toluene as an organic solvent were charged into a vessel having a volume of 2 L capable of being heated and cooled and equipped with a thermometer, a reflux cooling pipe, and a stirring device. Next, the mixture was stirred at 90° C. to 100° C. for 5 hours in a nitrogen atmosphere, thereby obtaining a solution of a modified conjugated diene polymer having a solid concentration of 35% by mass.

### Examples 1 and 2

### (Preparation of Thermosetting Resin Composition (Varnish))

A thermosetting resin composition (varnish) having a solid concentration of 55% by mass was prepared by mixing and stirring each component shown in Table 1 in accordance with the content shown in Table 1 together with methyl ethyl ketone at room temperature.

(Production of Resin Film with Support)

The varnish obtained as described above was applied to a PET film (manufactured by Toray Industries, Inc., thickness: 50 μm, surface roughness Rz: 8.5 μm, product name: Lumirror 50-X42, “Lumirror” is a registered trademark, the same applies hereinafter) which is a support having concave and convex using a comma coater, and then heated and dried at 120° C. for 3 minutes to produce a resin film with a support. The thickness of the resin film after drying was 10 μm.

### (Production of Prepreg)

Two sheets of the resin film with a support obtained as described above were prepared. One sheet of the resin film with a support was disposed on each of the front and back surfaces of a glass woven fabric (NE glass, manufactured by Asahi Kasei Corporation) having a thickness of 15 m such that the resin film of the resin film with a support was in contact with the glass woven fabric. The thus-obtained laminate of “PET film/resin film/glass cloth/resin film/PET film” was vacuum laminated using a vacuum laminating apparatus under the conditions of a heating platen temperature of 100° C., a crimping pressure of 0.3 MPa, a vacuum degree of 100 kPa or less, and a vacuum time of 20 seconds, then the PET film of the support was peeled off, and then heated and dried at 130° C. for 3 minutes to produce a prepreg having a thickness of 30 μm. The thickness of the prepreg was the average value of values obtained by measuring arbitrary five portions with a horizontal pedestal and a digimatic indicator (manufactured by Mitutoyo Corporation).

For the obtained prepreg, each evaluation and measurement were performed by the method described above. The results are shown in Table 1.

### (Production of Double-Sided Copper-Clad Laminate)

A low-profile copper foil having a thickness of 12 μm (3M-VLP12, manufactured by Mitsui Mining & Smelting Co., Ltd., the above-mentioned “VLP” is a registered trademark) was disposed on the upper and lower sides of the obtained prepreg so that the M surface (mat surface) was in contact with the prepreg, and then subjected to heat and pressure molding under conditions of a temperature of 230° C., a pressure of 3.0 MPa, and a time of 90 minutes, thereby producing a double-sided copper-clad laminate (thickness: 0.30 mm).

The relative dielectric constant (Dk) of the obtained double-sided copper-clad laminate was measured by the method described above. The results are shown in Table 1.

### Comparative Example 1

A prepreg and a double-sided copper-clad laminate were produced by performing the same operation as in Example 1 except that a PET film (manufactured by Toray Industries, Inc., thickness: 50 μm, surface roughness Rz: 6.5 μm, trade name: Lumirror 50-X44) was used instead of the PET film (manufactured by Toray Industries, Inc., thickness: 50 μm, surface roughness Rz: 8.5 μm, trade name: Lumirror 50-X42) in Example 1. The evaluation and measurement results are shown in Table 1.

### Comparative Example 2

A prepreg and a double-sided copper-clad laminate were produced by performing the same operation as in Example 2 except that a PET film (manufactured by Toray Industries, Inc., thickness: 50 μm, surface roughness Rz: 6.5 μm, trade name: Lumirror 50-X44) was used instead of the PET film (manufactured by Toray Industries, Inc., thickness: 50 μm, surface roughness Rz: 8.5 μm, trade name: Lumirror 50-X42) in Example 2. The evaluation and measurement results are shown in Table 1.

### Comparative Example 3

A prepreg and a double-sided copper-clad laminate were produced by performing the same operation as in Example 1 except that a PET film (manufactured by TOYOBO Co., Ltd., thickness: 50 μm, surface roughness Rz: 0.1 μm, trade name: Purex A5300, “Purex” is a registered trademark, the same applies hereinafter) was used instead of the PET film (manufactured by Toray Industries, Inc., thickness: 50 μm, surface roughness Rz: 8.5 μm, trade name: Lumirror 50-X42) in Example 1. The evaluation and measurement results are shown in Table 1.

### Comparative Example 4

A prepreg and a double-sided copper-clad laminate were produced by performing the same operation as in Example 2 except that a PET film (manufactured by TOYOBO Co., Ltd., thickness: 50 μm, surface roughness Rz: 0.1 μm, trade name: Purex A5300) was used instead of the PET film (manufactured by Toray Industries, Inc., thickness: 50 μm, surface roughness Rz: 8.5 μm, trade name: Lumirror 50-X42) in Example 2. The evaluation and measurement results are shown in Table 1.

TABLE 1

| | | | | | Comparative |
|---|---|---|---|---|---|
| | | | Examples | | Example |
| | | Unit | 1 | 2 | 1 |
| (A) Thermosetting resin | Maleimide compound A-1 | Parts by | 80 | 64 | 80 |
| | Maleimide compound A-2 | mass | | 21 | |
| (B) Compound having | Styrene-based thermoplastic elastomer | Parts by | 10 | 5 | 10 |
| structural unit (b1) | B-1 | mass | | | |
| derived from conjugated | | | | | |
| diene compound | | | | | |
| (C) Inorganic filler | Inorganic filler C-1 | % by | 38 | 19 | 38 |
| | | volume*¹ | | | |
| (D) Compatibilizer | Modified polyphenylene ether D-1 | Parts by | 10 | | 10 |
| | Modified conjugated diene polymer D-2 | mass | | 10 | |
| (E) Curing accelerator | Curing accelerator E-1 | phr*² | 2.0 | 2.0 | 2.0 |
| | Curing accelerator E-2 | | 0.1 | 0.1 | 0.1 |
| Evaluation and | 1. Existing ratio of concave portion in | % | 59 | 59 | 26 |
| measurement | concave-convex shape of prepreg surface | | | | |
| results | 2. Surface roughness (Rz) of prepreg | μm | 13.2 | 13.2 | 11.2 |
| | 3. Adhesiveness between prepregs | — | A | A | B |
| | 4. Relative dielectric constant (Dk) | — | 3.0 | 2.9 | 3.0 |
| | (10 GHz) | | | | |

| | | | Comparative Example | | |
|---|---|---|---|---|---|
| | | Unit | 2 | 3 | 4 |
| (A) Thermosetting resin | Maleimide compound A-1 | Parts by | 64 | 80 | 64 |
| | Maleimide compound A-2 | mass | 21 | | 21 |
| (B) Compound having | Styrene-based thermoplastic elastomer | Parts by | 5 | 10 | 5 |
| structural unit (b1) | B-1 | mass | | | |
| derived from conjugated | | | | | |
| diene compound | | | | | |
| (C) Inorganic filler | Inorganic filler C-1 | % by | 19 | 38 | 19 |
| | | volume*¹ | | | |
| (D) Compatibilizer | Modified polyphenylene ether D-1 | Parts by | | 10 | |
| | Modified conjugated diene polymer D-2 | mass | 10 | | 10 |
| (E) Curing accelerator | Curing accelerator E-1 | phr*² | 2.0 | 2.0 | 2.0 |
| | Curing accelerator E-2 | | 0.1 | 0.1 | 0.1 |
| Evaluation and | 1. Existing ratio of concave portion in | % | 26 | 0.1 | 0.1 |
| measurement | concave-convex shape of prepreg surface | | | | |
| results | 2. Surface roughness (Rz) of prepreg | μm | 11.2 | 1.9 | 1.9 |
| | 3. Adhesiveness between prepregs | — | C | C | C |
| | 4. Relative dielectric constant (Dk) | — | 2.9 | 3.0 | 2.9 |
| | (10 GHz) | | | | |

*¹% by volume with respect to the total amount of solid contents
*²Content (parts by mass) with respect to 100 parts by mass of the component (A).
The blending amount of each component is an amount in terms of solid content when a solution or a dispersion is used.

Details of each component shown in Table 1 are as follows.

### [(A) Thermosetting Resin]

Maleimide compound A-1: indane ring-containing aromatic bismaleimide
Maleimide compound A-2: biphenyl aralkyl type maleimide
   [(B) Compound Having Structural Unit (b1) Derived from Conjugated Diene Compound]
Styrene-based thermoplastic elastomer B-1: a hydride of a styrene-butadiene-styrene block copolymer (SEBS), a hydrogenation rate of 95 mol % or more, a styrene content of 30% by mass, and a weight-average molecular weight (Mw)=70,000

### [(C) Inorganic Filler]

Inorganic filler C-1: fused spherical silica, average particle diameter=0.5 m

### [(D) Compatibilizer]

Modified polyphenylene ether D-1: both ends methacrylic-modified polyphenylene ether derivative represented by the following formula, weight-average molecular weight=1,700

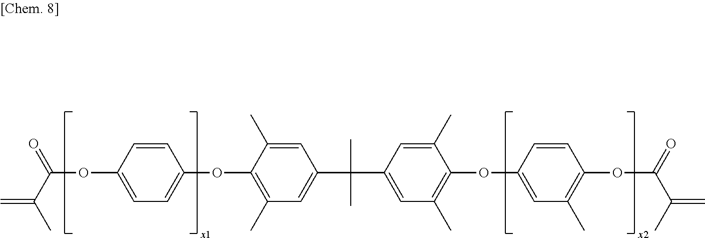

(In the above formula, x1 and x2 are each independently 0 to 20.)
Modified conjugated diene polymer D-2: a modified conjugated diene polymer prepared in Production Example 1
   [(E) Curing accelerator]
Curing accelerator E-1: α,α′-bis(t-butylperoxy)diisopropylbenzene
Curing accelerator E-2: isocyanate mask imidazole “G8009L” (trade name, manufactured by DKS Co., Ltd.)

From the results of Table 1, it can be seen that in Examples 1 and 2, although a compound having a structural unit derived from a conjugated diene compound is contained in order to lower the relative dielectric constant (Dk), since the existing ratio of the concave portion in the concave-convex shape is 59%, the adhesiveness between prepregs is reduced.

On the other hand, in Comparative Examples 1 to 4 in which a compound having a structural unit derived from a conjugated diene compound was contained in order to similarly reduce the relative dielectric constant (Dk), when the existing ratio of the concave portion in the concave-convex shape was 26% or 0.1%, the adhesiveness between prepregs was high.

1. A prepreg having a concave-convex shape on the surface, the prepreg comprising a thermosetting resin composition comprising (A) a thermosetting resin and (B) a compound having a structural unit (b1) derived from a conjugated diene compound, or a semi-cured product of the thermosetting resin composition, wherein an existing ratio of a concave portion in the concave-convex shape is 30 to 90%.

2. The prepreg according to claim 1, wherein the prepreg has a surface roughness (Rz) of 12.0 μm or more.

3. The prepreg according to claim 1, wherein the component (A) contains at least one selected from the group consisting of an epoxy resin, a maleimide compound, a phenol resin, a polyimide resin, a cyanate resin, an isocyanate resin, a benzoxazine resin, an oxetane resin, an amino resin, an unsaturated polyester resin, an allyl resin, a dicyclopentadiene resin, a silicone resin, a triazine resin, and a melamine resin.

4. The prepreg according to claim 1, wherein in the component (B), the structural unit (b1) derived from a conjugated diene compound is a 1,2-bond unit of butadiene, a 1,4-bond unit of butadiene, a 3,4-bond unit of isoprene, a 1,4-bond unit of isoprene, or a bond unit in which at least one selected from these bond units is hydrogenated.

5. The prepreg according to claim 1, wherein in the thermosetting resin composition, a content of the component (B) is 1% by mass or more and less than 14% by mass with respect to a total sum of resin components.

6. The prepreg according to claim 1, wherein the thermosetting resin composition further comprises (C) an inorganic filler.

7. The prepreg according to claim 6, wherein in the thermosetting resin composition, a content of the component (C) is 1 to 50% by volume with respect to a total sum of solid contents.

8. The prepreg according to claim 1, wherein the thermosetting resin composition further comprises (D) a compatibilizer.

9. The prepreg according to claim 1, wherein the thermosetting resin composition further comprises (E) a curing accelerator.

10. A laminate comprising a cured product of the prepreg according to claim 1, and a metal foil.

11. A printed wiring board comprising a cured product of the prepreg according to claim 1.

12. A semiconductor package comprising the printed wiring board according to claim 11, and a semiconductor element.
